(19) United States
(12) Patent Application Publication
(10) Pub. No.: US 2021/0281040 A1
(43) Pub. Date: Sep. 9, 2021

(54) LASER DIODE PACKAGING MODULE, DISTANCE DETECTION DEVICE, AND ELECTRONIC DEVICE

(71) Applicant: SZ DJI TECHNOLOGY CO., LTD., Shenzhen (CN)

(72) Inventors: Xiang LIU, Shenzhen (CN); Xiaoping HONG, Shenzhen (CN); Shuai DONG, Shenzhen (CN)

(21) Appl. No.: 17/330,377

(22) Filed: May 25, 2021

Related U.S. Application Data
(63) Continuation of application No. PCT/CN2018/117471, filed on Nov. 26, 2018.

(51) Int. Cl. H01S 5/0237; H01S 5/068

(52) U.S. Cl. CPC H01S 5/0237; H01S 5/06825

(57) ABSTRACT

The present disclosure provides a laser diode package. The package includes a sealing body, a laser diode chip placed in the sealing body, and a shaping element disposed on an outer surface of the sealing body and configured to shape light emitted from the laser diode chip.

### CROSS-REFERENCE TO RELATED APPLICATIONS

This application is a continuation of International Application No. PCT/CN2018/117471, filed on Nov. 26, 2018, the entire content of which is incorporated herein by reference.

### TECHNICAL FIELD

The present disclosure relates to the technical field of integrated circuit and, more specifically, to a laser diode packaging module, a distance detection device, and an electronic device.

### BACKGROUND

Lidar is a perception system of the outside world, which can obtain the three-dimensional (3D) information of the outside world. The principle of lidar is to actively transmit laser pulse signals to the outside, detect the reflected echo signals, and determine the distance of an object to be measured based on the time difference between the transmission of the laser pulse signal and the receipt of the reflected echo signal. Combining the distance of the object to be measured with the transmission angle information of the light pulse, the 3D depth information of the object can be reconstructed.

The lidar system needs to detect the distance of the object to be measured at different angles. The lidar system needs to have the ability to obtain wider range and more uniform spatial position information in a shorter period of time. The wider range here refers to the static field of view (FOV) of the lidar, and more uniform means that the detected points can be more evenly distributed within the dynamic scanning range of the lidar, rather than concentrate in some of the scanning areas.

A single chip/light emitting point is generally used as a light source in conventional solutions. With this single-point/single-line solution, when the energy is sufficient, the static lighting FOV of the light source is very limited. For the target of the same area, more scanning is needed, which requires high motor speed and circuit processing speed. In the dynamic scanning scenario, the coverage rate of this type of light source to the target is low, and there will be more scanning blind areas in practice. In addition, with this type of solution, the driving current of a single light source is relatively high, the reserved power is limited, and the device is used for a long period of time near full power, which leads to shortened service life.

In addition, in lidar/distance detection systems, to detect targets that are farther away, higher laser power is needed, but higher laser power may be incompatible with safety regulations. Therefore, a narrower pulse signal (in ns level) can be used. Narrow pulse signals are very easy to cause an increase in the distributed inductance on the circuit. This part of the inductance will not only cause an increase in energy consumption, but also cause the deformation and expansion of the signal, which affects the power consumption and response speed of the device. Conventional in-line packaged devices have large distributed inductance and limited heat dissipation capacity, which has great limitations for such fast-response narrow pulse applications. In addition, there are also packaging structures that use transistor outline (TO) or potting for a single chip/chip/light emitting point on the market. TO packaging technology refers to the transistor outline or through-hole packaging technology, that is, fully enclosed packaging technology. The chip heat dissipation path of the above packaging technology is too long, the heat dissipation capacity is limited, and it is not easy to expand the number of chips and the power level. Further, the structure of multi-chip, side patch, overall plastic or potting is not yet available on the market.

Therefore, in order to solve the above technical problems, the current laser packaging needs to be improve.

### SUMMARY

One aspect of the present disclosure provides a laser diode package. The package includes a sealing body, a laser diode chip placed in the sealing body, and a shaping element disposed on an outer surface of the sealing body and configured to shape light emitted from the laser diode chip.

Another aspect of the present disclosure provides a distance detection device. The distance detection device includes a distance detection module including a laser diode package configured to emit a laser pulse sequence. The laser diode package includes a sealing body; a laser diode chip placed in the sealing body; a shaping element disposed on an outer surface of the sealing body and configured to shape light emitted from the laser diode chip; and a detector configured to receive at least part of the laser pulse sequence reflected by an object, and obtain a distance between the distance detection device and the object based on a received light beam.

### BRIEF DESCRIPTION OF THE DRAWINGS

In order to illustrate the technical solutions in accordance with the embodiments of the present disclosure more clearly, the accompanying drawings to be used for describing the embodiments are introduced briefly in the following. It is apparent that the accompanying drawings in the following description are only some embodiments of the present disclosure. Persons of ordinary skill in the art can obtain other accompanying drawings in accordance with the accompanying drawings without any creative efforts.

FIG. 1 is a schematic diagram of a structure of a laser diode chip in a laser diode packaging module according to an embodiment of the present disclosure.

FIG. 2 is a schematic diagram of a spot of a light beam emitted by the laser diode chip.

FIG. 3A is a cross-sectional view of the laser diode packaging module according to an embodiment of the present disclosure.

FIG. 3B is a cross-sectional view of the laser diode packaging module according to another embodiment of the present disclosure.

FIG. 4A is a front view of a structure of the laser diode packaging module according to an embodiment of the present disclosure.

FIG. 4B is a top view of the structure of the laser diode module shown in FIG. 4A.

FIG. 5A is a front view of the structure of the laser diode packaging module according to another embodiment of the present disclosure.

FIG. 5B is a top view of the structure of the laser diode module shown in FIG. 5A.

FIG. 6A is a front view of the structure of the laser diode packaging module according to another embodiment of the present disclosure.

FIG. 6B is a top view of the structure of the laser diode module shown in FIG. 6A.

FIG. 7 is a schematic diagram of a distance detection device according to an embodiment of the present disclosure.

FIG. 8 is a schematic diagram of the distance detection device according to another embodiment of the present disclosure.

### DETAILED DESCRIPTION OF THE EMBODIMENTS

In order to make the objectives, technical solutions, and advantages of the present disclosure more clear, the technical solutions in the embodiments of the present disclosure will be described below with reference to the drawings. It will be appreciated that the described embodiments are some rather than all of the embodiments of the present disclosure. It should be understood that the present disclosure is not limited by the example embodiments described herein. Other embodiments conceived by those having ordinary skills in the art on the basis of the described embodiments without inventive efforts should fall within the scope of the present disclosure.

In the following description, numerous specific details are given in order to provide a more thorough understanding of the embodiments of the present disclosure. However, it is obvious to those skilled in the art that the present disclosure can be implemented without one or more of these details. In some embodiments, in order to avoid confusion with the present disclosure, some technical features known in the art are not described.

It should be understood that the present disclosure can be implemented in different forms and should not be construed as being limited to the embodiments presented here. On the contrary, the provision of these embodiments will make the disclosure more thorough and complete, and will fully convey the scope of the present disclosure to those skilled in the art.

The terminology used herein is for the purpose of describing particular embodiments and is not intended to limit the inventive concept. As used herein, the singular forms “a”, “an” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof. As used herein, the terms “and/or” includes any and all combinations of related listed items.

In order to thoroughly understand the present disclosure, a detailed structured will be provided in the following description to explain the technical solutions provided in the present disclosure. The example embodiments of the present disclosure are described in detail below. However, in addition to these details descriptions, the present disclosure may also have other embodiments.

In order to improve the conventional technology described above, the present disclosure provides a laser diode packaging module. The packaging module may include a sealing body, a laser diode chip embedded in the sealing body, and a shaping element disposed on the outer surface of the sealing body for shaping the light emitted from the laser diode chip.

The packaging module of the present disclosure can be individually driven and controlled by multiple chips and sealed as a whole, the spacing accuracy between the chips can be accurately controlled, and the short-distance design of the driver module and the laser diode chip can also be realized, which can realize the short-range drive of multiple chips at the chip level, reduce the influence of volatiles and circuit inductance of the driver module, significantly reduce the circuit system interference caused by the packaging structure, reduce the size of the device, obtain a higher power density, and realize a small and lightweight design. Finally, the introduction of a thermal conductive layer and a chip package can shorten the heat dissipation path of the chip, increase the heat dissipation channel, and reduce the thermal resistance. Compared with conventional TO or in-line packaged devices, the heat dissipation capacity is greatly improved, and it is easy to realize the expansion of high-density multi-chip area array structure.

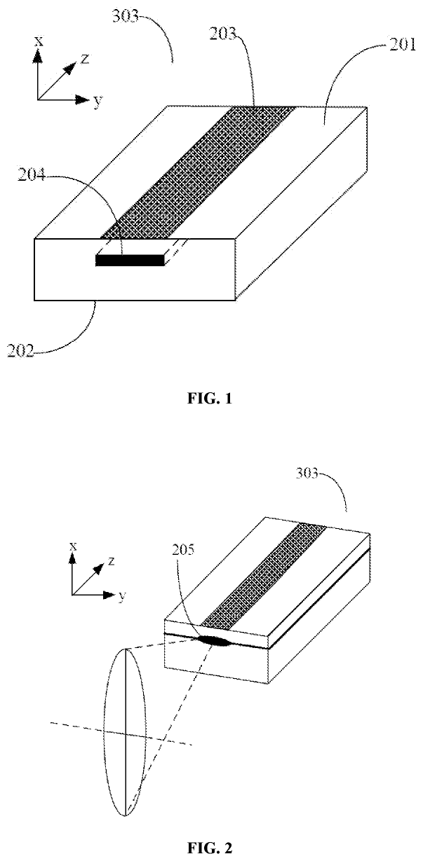

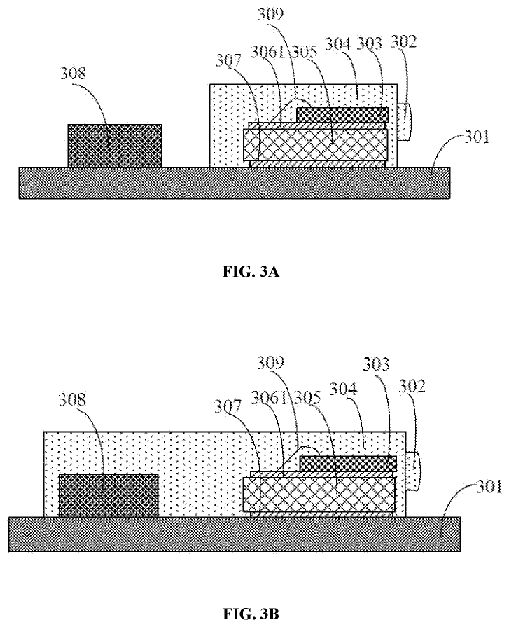

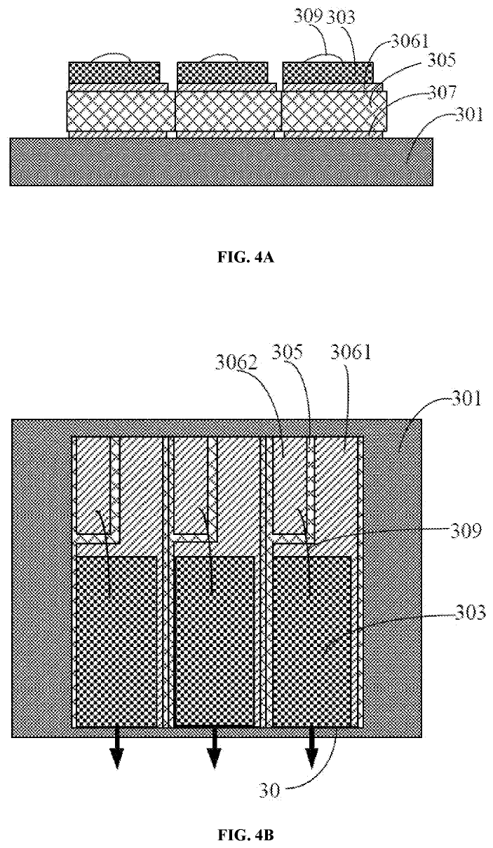

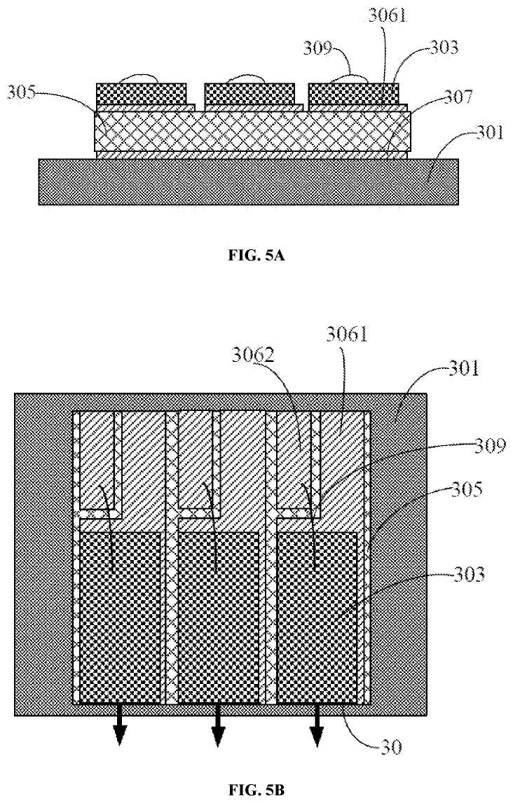

Hereinafter, specific embodiments of the laser diode packaging module of the present disclosure will be described in detail with reference to FIG. 1, FIG. 2, FIG. 3A, FIG. 3B, FIG. 4A, FIG. 4B, FIG. 5A and FIG. 5B. In the case where there is no conflict between the exemplary embodiments, the features of the following embodiments and examples may be combined with each other.

As shown in FIG. 3A, the packaging module includes a substrate 301 for carrying a laser diode chip. The substrate can be used for mounting on a circuit board, and the substrate 301 can serve the function of fixing, sealing, and heat conduction.

In some embodiments, the substrate 301 may include hard materials with high thermal conductivity to increase the heat dissipation effect of the packaged module. For example, the substrate 301 may be a metal substrate, a glass substrate, a silicon wafer substrate, an alloy substrate, a printed circuit board (PCB) substrate, a ceramic substrate, a pre-mold substrate, etc. In some embodiments, the ceramic substrate may be an aluminum nitride or aluminum oxide substrate.

The PCB may be made of different components and a variety of complex process technologies. The structure of the PCB may include a single-layer, double-layer, multi-layer structure, and different hierarchical structure may have different manufacturing methods.

In some embodiments, the PCB is mainly composed of pads, through holes, mounting holes, wires, components, connectors, filing, electrical boundaries, etc.

Further, the conventional layer structures of the PCB includes single-layer PCB, double-layer PCB, and multi-layer PCB. The specific structures are described below.

(1) Single-layer PBC: a circuit board with copper on one side and no copper on the other side. Generally the components are placed on the side without copper, and the side with copper is mainly used for wiring the welding.

(2) Double-layer PCB: a circuit with copper on both sides. Generally one side is called the top layer, and the other side is call the bottom layer. Generally, the top layer is used as the surface for placing components and the bottom layer is used as the welding surface for components.

(3) Multi-layer PCB: a circuit board including multiple working layers. In addition to the top and bottom layers, it also includes several intermediate layers. Generally the intermediate layers can be used as a wiring layer, signal layer, power layer, ground layer, etc. The layers are insulated from each other, and the connection between the layers is generally achieved via through holes.

The PCB may include many types of working layers, such as the signal layer, protective layer, silk screen layer, internal layer, etc., which will not be repeated here.

In addition, the substrate described in the present disclosure may also be a ceramic substrate. The ceramic substrate may refer to a special processed board in which copper foil is directly bonded to alumina (Al₂O₃) or aluminum nitride (AlN) ceramic substrate surface (single-sided or double-sided) at a high temperature. The ultra-thin composite substrate from this process has excellent electrical insulation properties, high thermal conductivity, excellent solderability, and high adhesion strength, and can be etched into various patterns like a PCB board, and has a large current-carrying capacity.

Further, the substrate may be a pre-mold substrate. The pre-mold substrate may include injection molded wires and pins, and the injection molded wires may be embedded in the main structure of the substrate. The pins may be positioned on the surface of the main structure of the substrate, such as the inner surface and/or the outer surface, to realize the electrical connection between the substrate and the laser diode die, the driving chip, and the circuit board, respectively.

The preparation method of the pre-mold substrate may include a conventional injection process, planer excavation process, and molding process, which will not be repeated here.

The injection material of the pre-mold substrate may be a conventional material, such as a thermally conductive plastic material, etc., and is not limited to a certain type of material. The shape of the pre-mold substrate is limited by the injection frame, and is not limited to a certain type of shape.

As shown in FIG. 3A, the laser diode packaging module further includes a laser diode chip 303 and a sealing body 304. The laser diode chip 303 is embedded in the sealing body 304. In some embodiments, the sealing body 304 can be used to protect the laser diode chip 303, and serve the functions of sealing, dustproofing, and moisture-proofing.

In some embodiments, the sealing body 304 may be mounted on the substrate 301, and the laser diode chip 303 may be sealed and fixed on the substrate 301, such that the laser diode chip 303 can be embedded in the sealing body 304. In other embodiments, the sealing body may seal the laser diode chip 303 and the substrate 301.

In some embodiments, the substrate 301 may not be used, and only the laser diode chip 303 may be embedded in the sealing body.

The material of the sealing body can be any suitable material with plasticity and high light transmittance. For example, the material of the sealing body may include transparent epoxy resin, optical glass, plastic with good light transmittance, or other organic substances with good light transmittance. The light transmittance of the material of the sealing body may be above 90% to ensure that while the laser diode chip is sealed, most of the outgoing beam emitted from the laser diode chip can pass through the sealing body and exit into the shaping element.

In some embodiments, the laser diode chip 303 may include a single light-emitting point, an integration of single light-emitting points, multiple light-emitting bars, or a combination thereof Alternatively the laser diode chip 303 may also be other suitable laser diode chip structures.

In some embodiments, a laser diode chip with a single light-emitting point can be taken as an example to describe the structure of a laser diode chip. The laser diode chip may be a side laser, that is, the side of the laser diode chip can emit light. In some embodiments, the shape of the laser diode chip may be a columnar structure, for example, it may be a cuboid structure, or it may be a polyhedron, a columnar, or other suitable shapes, which will not be listed here. In some embodiments, the light-emitting surface of the laser diode chip may be disposed on the side surface of one end of the columnar structure of the laser diode chip. In one example, the side surface may be the smallest surface of the laser diode chip.

In some embodiments, the laser diode chip 303 may have a cuboid structure, and the light-emitting surface of the laser diode chip may refer to the side surface at one end of the cuboid structure. FIG. 1 is a schematic diagram of a structure of a laser diode chip in a laser diode packaging module according to an embodiment of the present disclosure, and FIG. 2 is a schematic diagram of a spot of a light beam emitted by the laser diode chip. As shown in FIG. 1 and FIG. 2, the laser diode chip 303 includes a first electrode 201 and a second electrode 202 disposed opposite to each other.

In some embodiments, the first electrode 201 and the second electrode 202 may both be metalized electrodes, which can be used as external mechanical fixing and electrical connection points of the laser diode chip. For example, as shown in FIG. 1 and FIG. 2, along the z-direction is the cavity length direction of the laser diode chip, and the first electrode 201 and the second electrode 202 are respectively disposed on two opposite surfaces along the x-direction. In some embodiments, the first electrode 201 may be a p-electrode, and the second electrode 202 may be an n-electrode. A contact area 203 is also formed on the surface where the first electrode 201 is disposed. The contact area 203 can be used to lead out the first electrode 201 and electrically connect to an external circuit. In some embodiments, a light-emitting area 204 of the laser diode chip can be close to the first electrode 201, and the light-emitting area 204 can also be an active area of the laser diode chip.

It should be noted that exit surface (also referred to as the light-emitting surface) may refer to the surface of the laser diode die emitting light. The exit surface may also be the side surface of the right side of the laser diode die, it may also be the front surface and rear surface of the laser diode die, and is not limited to the above example.

As shown in FIG. 2, a light-emitting point (also referred to as the light-emitting surface) 205 is disposed on the side of the laser diode chip. In some embodiments, the size of the area of the light-emitting point 205 may be selected based on the requirements of the device. For example, the area of a single light-emitting point 205 may be approximately between 1 μm×100 μm to 1 μm×200 μm. The outgoing beam of the laser diode chip may be an elliptical spot. As shown in FIG. 2, the divergence of the beam along the x-direction is relatively large, which can be referred to as the fast axis of the laser, and the divergence of the beam along the y-direction is relatively small, which can be referred to as the slow axis of the laser. Due to the difference in the beam waist and divergence angle of the fast and slow axes, the beam quality BPP (the product of the beam parameters in the slow axis and the fast axis direction) of the semiconductor laser can be very different. If the beam is not reshaped, it may be inconvenient in the practical application of laser diode chips.

Further, in the application of laser diode chips, a shaping element composed of multiple lenses is generally glued on the substrate to shape the output beam of the laser diode chip. This type of packaging structure requires high process assembly requirements and large layout area, which is inconvenient to the miniaturization of the device.

Therefore, the packaging module of the present disclosure further includes a shaping element 302. The shaping element 302 can be disposed on the outer surface of the sealing body 304 for shaping the light emitted form the laser diode chip 303. Further, the shaping element 302 can be used to collimate and/or shape the emitted light beam of the laser diode chip 303 in the fast axis and/or slow axis direction, thereby making the spot shape, energy distribution, and divergence angle of the outgoing beam meeting the predetermined requirements, improving the beam quality, and increasing the radiation utilization rate of the laser diode chip.

In some embodiments, the shaping element 302 and the sealing body 304 may be integrally formed. The integrated shaping element and sealing body can conveniently and compactly realize beam collimation and/or shaping, reduce the size of the packaging structure, and replace the conventional multi-lens cementing and housing sealing method, reduce the material processing and process assembly requirements, and reduce the cost.

The material of the shaping element can be any suitable material with plasticity and high light transmittance. For example, the material of the shaping element may include transparent epoxy resin, optical glass, plastic with good light transmittance, or other organic substances with good light transmittance. Further, the transmittance of the shaping element 302 to the emitted light of the laser diode chip may be above 90% to ensure that most of the emitted light emitted from the laser diode chip can be shaped after passing through the shaping element, and the light spot with a certain shape and divergence angle can continue to be directed towards subsequent applications. In some embodiments, an optical antireflection film (not shown in the accompanying drawings) corresponding to the wavelength of the emitted light emitted by the laser diode chip may be plated on the surface of the shaping element, which can increase the intensity of the transmitted light beam. The thickness of the antireflection film may be equal to or close to the wavelength of the emitted light emitted by the laser diode chip.

Any suitable method can be used to seal the laser diode chip, and at the same time, the shaping element and the sealing body can be integrally formed and adhered to the substrate 301. In some embodiments, the sealing body 304 and the shaping element 302 can be integrally formed and adhered to the substrate 301 by injection molding or potting. Alternatively, the sealing body 304 may be bonded and sealed on the substrate 301 by means of compression molding or secondary bonding.

In other embodiments, the shaping element 302 can also be fixed on the sealing body 304 by welding or gluing, which can achieve collimation and/or shaping conveniently and compactly, and reduce the size of the packaging structure.

The shaping element 302 can be any suitable element known to those skilled in the art. In some embodiments, the shaping element 302 may include a cylindrical lens array structure, a D-shaped lens array structure, an optical fiber rod array structure, or an aspheric lens array structure. For example, to collimate and/or shape the fast axis beam (e.g., by compression, that is, compress the divergence angle of the beam), the shaping element may include one or more of a cylindrical lens, a D lens, a fiber rod, an aspheric lens, etc. To collimate and/or shape the slow axis beam, the shaping element may include one or more of a cylindrical lens array structure, a D-shaped lens array structure, an optical fiber rod array structure, and an aspheric lens array structure.

In some embodiments, in order to realize the collimation and/or shaping of the light beam by the shaping element 302, the light exit surface of the laser diode chip may be set at or within one focal length of the shaping element 302.

In some embodiments, as shown in FIG. 3A and FIG. 3B, in order to increase the heat dissipation efficiency of the laser diode chip, the packing module of the present disclosure further includes a thermal conductive layer 305. The thermal conductive layer 305 can be embedded in the sealing body 304. In some embodiments, the laser diode chip 303 can be disposed on the thermal conductive layer 305. By using the thermally conductive layer and the chip packaging, the thermally conductive layer may directly transfer heat to the housing, which shortens the heat dissipation path of the laser diode chip 303, increase the heat dissipation channel, reduce the thermal resistance, and effectivity improve the heat dissipation capacity and power of the device. Compared with the TO or in-line packaging devices, the heat dissipation capacity of the structure described above is significantly improved, and it is easier to realize the expansion of the high-density multi-chip area array structure by adopting this structure.

The thermal conductive layer 305 can fix and support the laser diode chip, and also perform thermal and electrical conduction functions. The material of the thermal conductive layer 305 can be any suitable material with high thermal conductivity, especially an insulating material with high thermal conductivity. For example, the material of the thermal conductive layer may include one or more of ceramic copper-clad, ceramic copper-plated, ceramic metallization, silicon wafer metallization, and glass metallization.

Although FIG. 3A and FIG. 3B show the structure of the packaging module of the present disclosure including a thermally conductive layer and a laser diode chip disposed on the thermally conductive layer, the structure of the packaging module of the present disclosure is not limited to the above structure. For example, the packaging module may also include two or more laser diode chips.

FIG. 4A and FIG. 4B show a multi-chip stacked array packaging module structure. The packaging module may include two or more laser diode chips 303 and thermal conductive layers 305, and each of the two or more laser diode chips 303 may be respectively disposed on a different thermal conductive layer 305. In order to better illustrate the structure and relationship between the laser diode chip and the thermal conductive layer, the structure of the sealing body and the shaping element are not shown in FIG. 4A and FIG. 4B. In the structure of this embodiment, each laser diode chip 303 and a thermal conductive layer 305 can be correspondingly packaged into a chip on carrier (COC) structure, which can be packaged into a multi-chip structure by a plurality of COCs arranged in a predetermined direction. This type of packaging method has greater flexibility, the number of chips is variable, the pitch between the chips can be limited, and each COC can be packaged separately, which is easy to achieve precise alignment and mass automatic production. Further, a single COC can also be tested and screened for some high-performance requirements (such as multi-wavelength, narrow spectrum, etc.), which reduces the rework rate in subsequent processes. Furthermore, two COCs can be positioned close to each other, which has lower requirements on tooling and fixtures.

FIG. 5A and FIG. 5B show a multi-chip stacked array packaging module structure. The packaging module may include two or more laser diode chips 303, and the two or more laser diode chips 303 can be disposed on the same thermal conductive layer 305. A plurality of laser diode chips 303 can be packaged on the same thermal conductive layer 305. A first metallization layer 3061 opposite to the first electrode of each laser diode chip 303, and a second metallization layer 3062 for electrically connecting the second electrode of the laser diode chip 303 can be disposed on the surface on which the laser diode chip 303 is attached to the thermal conductive layer 305. The thermal conductive layer 305 with multiple laser diode chips 303 attached to it can be attached to the substrate 301 to realize the multi-chip control output function. In this structure, multiple chips can be packaged and formed in one process, the materials used can be reduced, the processes are relatively simple, and the patterning requirements for the metallization layer on the thermal conductive layer 305 can be high. The pitch between chips can be determined by the level of graphical processing. Multiple chips can be accurately positioned at the same time, which requires high precision in tooling and fixtures, and is suitable for application where large-scale fixed solutions are required.

In some embodiments, as shown in FIG. 3A, FIG. 3B, FIG. 4A, FIG. 4B, FIG. 5A, and FIG. 5B, the thermal conductive layer 305 includes a first surface and a second surface opposite to each other. In some embodiments, the laser diode chip 303 may be disposed on the first surface of the thermal conductive layer 305, and the second surface may be mounted on the surface of the substrate 301.

In some embodiments, the thermal conductive layer 305 can be mounted on the surface of the substrate 301 by solder. The material of the solder can be any suitable metal or alloy material. For example, the solder may include SnAgCu, SnCu, AuSn, AuGe, SnFb, In, or In-based alloy. Since the solder is a metal or metal alloy, it generally has good thermal conductivity and electrical conductivity. Therefore, the use of solder can make a good electrical and thermal contact between the thermal conductive layer and the substrate, forming a good electrical and thermal conductive path.

In some embodiments, the laser diode chip may include a first electrode and a second electrode disposed opposite to each other, and the surface on which the first electrode is positioned may be mounted on the first surface of the thermal conductive layer 305. In some embodiments, the first electrode may be a p-electrode, and the second electrode may be an n-electrode. The p-electrode may be mounted on the first surface of the thermal conductive layer 305, and the first electrode and the second electrode of the laser diode chip may be disposed on a surface with a larger area than the light-emitting surface. This arrangement can facilitate the mounting of the chip, the packaging module structure of the present disclosure can be realized through the chip package, and it is also convenient for the position setting of the packaging module in the complete device. In addition, due to the large area, the heat dissipation area is relatively large, which can increase the heat dissipation efficiency of the chip, and the flip-chip packaging method such as mounting the p-electrode on the thermal conductive layer can also improve the heat dissipation efficiency of the chip.

In the embodiments of the present disclosure, the first metallization layer 3061 and the second metallization layer 3062 insulated from each other can be disposed on the first surface of the thermal conductive layer 305 to electrically connect the laser diode chip 303 and the substrate 301. In some embodiments, the first electrode may be mounted on the first metallization layer 3061 through a conductive adhesive layer (not shown in the accompanying drawings), and the second electrode may be electrically connected to the second metallization layer 3062 through a connecting wire 309.

The connecting wire 309 may be a conductor that functions as an electrical connection, thereby electrically connecting and conducting the second electrode of the laser diode chip with the second metallization layer 3062 on the thermal conductive layer. The number of the connecting wires 309 can be set based on actual needs, and multiple wires can be used side by side to realize the electrical connection between the second electrode and the second metallization layer 3062, and the arc of the wires can be pulled as low as possible. In some embodiments, the connecting wires 309 may include gold wires, gold ribbons, aluminum wires, copper foils, or other highly conductive alloys. The connection between the connecting wire and the second electrode and the second metallization layer 3062 can be realized in any suitable manner. For example, the connection can be realized by wire bonding or welding.

In some embodiments, different second metallization layers corresponding to different laser diode chips may also be spaced part from each other to avoid forming electrical connections between different laser diode chips.

In some embodiments, the area of the first metallization layer 3061 on the thermal conductive layer 305 may be larger than the area of the laser diode chip mounted on the thermal conductive layer, such that the first electrode of the thermal conductive layer can be drawn out.

In some embodiments, the second electrode may be electrically connected to the second metallization layer 3062 through a connecting wire 309.

It should be noted that in order to realize the extraction of the first electrode and the second electrode of the laser diode chip, a metal layer of the substrate for respectively extracting the first electrode and the second electrode may also be disposed on the substrate. A plurality of through holes can be arranged in the thermal conductive layer, and the first metallization layer can be electrically connected to the metal layer of the substrate for leading the first electrode through the through holes, thereby realizing the electrical connected between the first electrode and the substrate, and further leading the first electrode through the metal layer of the substrate to facilitate connection with other external devices or circuits. Similarly, the second metallization layer can be electrically connected to the metal layer of the substrate for leading out the second electrode through the through holes, thereby realizing the electrical connection between the second electrode and the substrate, and further leading the second electrode through the metal layer of the substrate to facilitate connection with other external devices or circuits

In some embodiments, a third metallization layer 307 may be disposed on the second surface of the thermal conductive layer 305 to connect the thermal conductive layer 305 and the substrate 301 to form good electrical and thermal paths.

In some embodiments, the laser diode die 303 may be a bare die, that is, a small piece of circuited “die” cut from a wafer, which is mounted on the substrate 300 by means of die bond. Die bond may refer to the process of bonding the die to a designated are of the substrate through glue, generally a conductive glue or an insulating glue, to form a thermal path or an electrical path to provide conditions for the subsequent wire bonding. The laser diode chip can be mounted using any suitable method. For example, the first electrode may be mounted on the first surface of the thermal conductive layer through a conductive adhesive layer (not shown in the accompanying drawings). The conductive adhesive layer not only has good electrical conductivity and excellent thermal conductivity, the material of the conductive adhesive layer (not shown in the accompanying drawings) may include conductive silver paste, solder, conductive glue, or conductive die attach film (DAF). In some embodiments, the conductive silver paste may be ordinary silver paste or nano-silver paste, and the solder may include, but is not limited to, AuSn or AnSn.

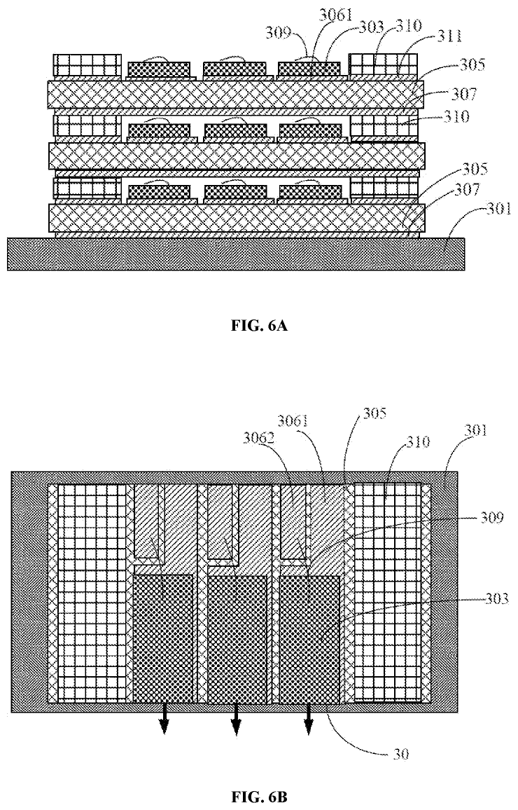

FIG. 6A and FIG. 6B show a multi-chip area array packaging module structure, and the packaging module can be applied to a multi-line/area array light source scene. The packaging module may include two or more layers of the thermal conductive layer 305 arranged in stack, where one or more laser diode chips 303 may be disposed on each layer of the thermal conductive layer 305. In some embodiments, two or more laser diode chips 303 may be disposed on each layer of the thermal conductive layer 305.

In some embodiments, two or more layers of the thermal conductive layer 305 may be disposed on the substrate 301, where the two or more layers of the thermal conductive layer 305 may be stacked in a direction parallel to the surface of the substrate 301. Alternatively, the two or more layers of the thermal conductive layer 305 may be stacked in a direction perpendicular to the surface of the substrate. FIG. 6A illustrates a case where three thermal conductive layers 305 are stacked in a direction perpendicular to the surface of the substrate 301. In this embodiment, this structure is used as an example to describe the stacked packaging structure.

In some embodiments, as shown in FIG. 6A, the packaging module further includes a space layer 310. The space layer 310 is disposed between two adjacent thermal conductive layers 305 to separate the adjacent thermal conductive layers 305 to realize physical fixation and thermal conduction.

In some embodiments, the space layer 310 may include two or more sub-spacers disposed on the thermal conductive layer at intervals. The number of the spacers may be selected based on the needs of the actual device, and the size of the interval between adjacent sub-spacers may be larger than the width of the laser diode chip. FIG. 6A illustrates a case where two sub-spacers are provided, and the two sub-spacers are respectively disposed at the edge of the thermal conductive layer 305, where the length of the sub-spacer is approximately the same as the edge length of the thermal conductive layer, or it can be slightly shorter than the edge length of the thermal conductive layer, such that the entire spacer can be positioned on the thermal conductive layer. In some embodiments, the length extension direction of the sub-spacer may be parallel to the length extension direction of the laser diode chip. In some embodiments, the laser diode chip 303 may be disposed on the thermal conductive layer 305 at the interval between adjacent sub-spacers.

In some embodiments, the space layer 310 may include two or more spacer columns disposed at intervals on the thermal conductive layer. The number of spacer columns can be selected based on the needs of device stability. For example, two or more spacer columns may be disposed at each of the two opposite edges of the thermal conductive layer, such that the thermal conductive layer can be stably separated.

In other embodiments, the sub-spacers and the spacer columns can be mixedly disposed. For example, the sub-spacers may be disposed at one side edge of the thermal conductive layer, and several spacer columns may be disposed at the edge of the opposite side.

The material of the space layer 310 can be any suitable material with good thermal conductivity. For example, the material of the spacer layer may include a conductor or a thermal conductive insulator. For example, the material of the space layer 310 may include copper, copper alloys, ALN, BeO, SiC, Si, diamond, and other high thermal conductivity materials. The spacer layer may be disposed between adjacent thermally conductive layers by any suitable method. For example, the space layer 310 may be disposed on the thermal conductive layer 305 by welding, adhesive bonding, or physical fixing.

In some embodiments, the distance between adjacent thermal conductive layers 305 may be greater than the thickness of the laser diode chip 303, such that the laser diode chip 303 can be placed on each thermal conductive layer 305. Further, the distance between adjacent thermal conductive layers 305 may be greater than the distance between the vertex of the arc of the connecting wire 309 and the surface of the laser diode chip attached to the connecting wire on the thermal conductive layer 305, thereby preventing the connecting wire from touching other thermal conductive layers to conduct electricity.

As shown in FIG. 6B, two or more laser diode chips 303 are disposed on each thermal conductive layer 305, and the distance between adjacent laser diode chips 303 can be determined by the patterning level of the metallization layer on the thermal conductive layer. For example, the minimum distance between adjacent chips may be 20 μm. The distance between adjacent (top to bottom, or left to right) laser diode chips 303 disposed on different thermal conductive layers 305 can be determined by the material processing level of the space layer 310 and the arc height of the connecting wire 309. For example, the minimum distance between adjacent (top to bottom, or left to right) laser diode chips 303 may be substantially 220 μm.

As shown FIG. 4B, FIG. 5B, and FIG. 6B, the light-emitting surface of the laser diode chip 303 may be positioned at the edge of the thermal conductive layer 305 to prevent the thermal conductive layer 305 from blocking the outgoing beam emitted by the laser diode chip and affecting the light-emitting efficiency of the laser diode chip.

In the above embodiment, when the packaging module includes two or more laser diode chips 303, a light-emitting surface 30 of each laser diode chip 303 may face the same direction. Alternatively, some of the light-emitting surfaces of two or more laser diode chips 303 may face a first direction, and some of the light-emitting surfaces may face a second direction opposite to the first direction. The specific arrangement can be selected and set based on device requirements.

In the foregoing embodiments, the packaging module may further include a driver module for controlling the emission of the laser diode chip. In the following description, a driver module 308 shown in FIG. 3A is used as an example to explain and describe the structure of the driver module. For other embodiments of the present disclosure, the driver module may also be applicable.

In one embodiment, as shown in FIG. 3A, the driver module 308 is disposed outside the sealing body 304. For example, the sealing body 304 may seal the thermal conductive layer 305 disposed on the substrate 301 and the laser diode chip 303 on the thermal conductive layer 305, and the driver module 308 may be mounted on the substrate 301 outside the sealing body 304.

In another embodiment, as shown in FIG. 3B, the driver module 308 and the laser diode chip 303 may be disposed in the same sealing body 304. For example, the sealing body 304 may seal the thermal conductive layer 305 disposed on the substrate 301, the laser diode chip 303 on the thermal conductive layer 305, and the driver module 308 on the substrate 301 on the outer side of the thermal conductive layer 305.

In other embodiments, the driver module and the laser diode chip may be disposed in different sealing bodies, that is, one sealing body may seal the driver module, and the other sealing body may seal the laser diode chip. For example, the driver module may be mounted on a substrate, one sealing body may seal the driver module, and the other sealing body may seal the thermal conductive layer and the laser diode chip disposed on the thermal conductive layer.

In some embodiments, the packaging module may include two or more laser diode chips, and the packaging module may further include a driver module for controlling the emission of the two or more laser diode chips. Each of the laser diode chips may be individually driven and controlled by one of the driver modules.

In other embodiments, the packaging module may include two or more laser diode chips, and the packaging module may further include a driver module for controlling the emission of the two or more laser diode chips. The two or more laser diode chips may be divided into several batches, and different batches may be independently driven and controlled by differing driver modules. For example, in the packaging module shown in FIG. 6A, the laser diode chips on the same layer can be used as a batch, and different batches (i.e., different layers) can be independently driven by different driver modules. Alternatively, laser diode chips on different layers with at least partially overlapping projections on the surface of the substrate can be used as one batch, and different batches can be independently driven by different driver modules.

In the above embodiment, the driver module that controls the emission of the 0.2 and the laser diode chip can be disposed at a close distance. Through this arrangement, the inductance between the laser diode chip and the driver module next to the laser diode chip in the current packaging and the distributed inductance on the line can be eliminated to reduce the distributed inductance of the packaged module, thereby realizing high-power laser emission, high-frequency fast response, and narrow-pulse laser drive, reducing the influence of volatiles in the driver module on the laser diode chip, and realizing a compact and lightweight design.

In some embodiments, in the packaged module, the laser diode chip may be placed as close to the driver module as possible. The shorter the distance between the laser diode chip and the driver module, the more effective the distributed inductance can be reduced. By setting the transmitter module, the loss on the distributed inductance will be much smaller, and it is easier to achieve high-power laser emission. Further, the reduction of the distributed inductance also makes it possible to drive narrow pulse lasers.

The driver module may further include one or more of FET devices or other types of switching devices, FET devices or drive chips of switching devices, needed resistors and capacitors, etc. These devices may be mounted on the substrate through a conductive material, such as a conductive adhesive (including but not limited to solder paste) through SMT

In the foregoing embodiments of the present disclosure, although FIG. 4A, FIG. 4B, FIG. 5A, FIG. 5B, FIG. 6A, and FIG. 6B do not show the structure of the sealing body, the shaping element, and the driver module, it is conceivable that these structures are also included in the foregoing embodiments.

In the embodiments of the present disclosure, after the thermal conductive layer, the laser diode chip, and the driver modules are disposed on the substrate, the sealing body can be formed by the packaging method such as injection molding or potting to seal the above structure. In addition, a shaping element can also be integrally formed on the outer surface of the sealing body while forming the sealing body. For a packaging module including two or more laser diode chips, the light-emitting surface of each light-emitting may correspond to one or more shaping element, or the light-emitting surface of multiple laser diode chips may correspond to the same shaping element. The specific number of the shaping elements can be adjusted based on actual structural requirements.

It should be noted that a packaging module including two or more laser diode chips, the two or more laser diode chips may be embedded in the same sealing body, or different laser diode chips may be embedded in different sealing bodies.

In some embodiments, the packaging module may further include a cover (not shown in the accompanying drawings) disposed on the surface of the substrate. A receiving space can be formed between the substrate and the cover. A light-transmitting area may be at least partially disposed on the cover, the sealing body and the shaping element may be disposed in the receiving space, and the light emitted from the shaping element may be emitted through the light-transmitting area.

In the embodiments of the present disclosure, the cover is not limited to a certain structure. The cover may be at least partially provided with a light-transmitting area, and the emitted light of the laser diode chip may be collimated and/or shaped by the shaping element, and then emitted through the light-transmitting area. For example, in some embodiments, the cover may be a metal shell with a glass window.

In some embodiments, the cover may include a U-shaped or a square cover body with a window, and a light-transmitting plate that covers the window to form the light-transmitting area, where the light-transmitting plate may be parallel to the first surface of the substrate, or the cover may be an all light-transmitting plate-like structure. Further, the cover may provide protection and an airtight environment for the chips enclosed in the cover.

As an example, the projection of the U-shaped cover with the window on the first surface of the substrate may be circular or other suitable shapes. The projection of the square cover on the first surface of the substrate is a square. The size of the square cover may match the size of the substrate, which can effectively reduce the package size.

The material of the cover may be any suitable material. For example, the material of the cover may include metal, resin, or ceramic. In one example, the material of the cover may use metal materials. The metal materials may be a material similar to the thermal expansion coefficient of the light-transmitting plate, such as a Kovar alloy. Since the thermal expansion coefficient of the cover and the light-transmitting plate is similar, therefore, when the light-transmitting plate is bonded to the window of the cover, the cracking of the light-transmitting plate due to the difference thermal expansion coefficient can be avoided. In some embodiments, the cover may be fixedly connected to the first surface of the substrate by welding. The welding may use any suitable welding method, such as parallel seam welding or store energy welding. In one example, the light-transmitting plate may also be bonded to the inner side of the window of the cover.

The light-transmitting plate may be made of commonly used light-transmitting materials, such as glass, which needs to have high passability to the laser wavelength emitted by the laser diode die.

In another example, the cover may be an all light-transmitting plate-like structure. The plate-shaped structure may use commonly used light-transmitting material, such as glass. The glass needs to have high passability to the laser wavelength emitted by the laser diode die. The overall structure of the substrate may be in the shape of a groove, and the groove may be a square groove or a circular groove. The cover may be disposed on top of the groove of the substrate and joined with the top surface of the substrate to cover the groove, and the receiving space may be formed between the substrate and the cover.

In the embodiments of the present disclosure, the cover may not be provided, and the various components may be provided on the substrate through the sealing body.

Any suitable process method can be used to prepare the packaging module in the foregoing embodiments. In the following description, a preparation method of the structure shown in FIG. 3A is taken as an example. The method will be described in detail below.

S1, bonding the laser diode chip 303 to the thermal conductive layer 305 by flip-chip or reflow using solder such as AnSn, AuSn, silver paste, or conductive glue. In some embodiments, the first metallization layer 3061 of the thermal conductive layer 305 may be pre-plated with solder, such as SnAu or In solder, and then the laser diode chip may be bonded to the thermal conductive layer by reflow.

S2, electrically connecting the second electrode (e.g., the n-electrode) of the laser diode chip 303 and the second metallization layer on the thermal conductive layer by wire bonding through a connecting wire 309 to lead out the second electrode.

S3, mounting the thermal conductive layer 305 on the substrate 301 by solder such as SnAgCu, SnFb, In, or In-based alloy.

S4, welding external lead electrodes (not shown in the accompanying drawings) to the first metallization layer and the second metallization layer on the thermal conductive layer 305, respectively.

S5, sealing the laser diode chip 303, the thermal conductive layer 305, and the connecting wires on the thermal conductive layer 305 by injection molding or pouring to complete the sealing of the laser diode chip. In some embodiments, the process temperature during injection molding or pouring may be lower than 140° C.

S6, adjusting the shaping element to ensure that the fast axis/slow axis light emission meets the requirements, then using a low shrinkage adhesive or solder to bond and fix the shaping element to the outer surface of the sealing body and correspond to the light-emitting surface of the laser diode chip. It should be noted that the shaping element and the sealing body may also be integrally formed in the process at S5.

S7, fixing the driver module 308 on the substrate 301, and connecting the positive/negative power supply electrodes of the driver module 308 to the lead electrodes outside the laser diode chip correspondingly to control the laser diode chip emission.

S8, performing normal test and diagnostics.

It should be noted that the manufacturing method of the packaging module of the present disclosure is not limited to the above processes, and may also include other processes or may also be implemented by changing the order of the processes.

Consistent with the present disclosure, the structure of the packaging module of the present disclosure can realize multi-chip stacked array/area array patch-type packaging, multiple chips can be individually driven and controlled and sealed as a whole, and the precision of the spacing between the chips can be accurately controlled, for example, the spacing may be controlled at a minimum of 200 μm. Further, the packaging structure and processes are simple, and it is easy to realize mass production. In addition, the integrated shaping element and sealing body structure can realize the beam compression and shaping conveniently and compactly, replace the multi-line cementing and shell sealing method, reduce material processing and process assembly requirements, and meet low-cost applications. Further, the use of a sealing body for sealing can not only prevent dust, condensation, and protect the chip, but also realize the close design of the driver module and the laser diode chip, which can realize the short-range drive of multiple chips at the chip level, reduce the influence of volatiles and circuit inductance of the driver module, significantly reduce the circuit system interference caused by the packaging structure, reduce the size of the device, obtain a higher power density, and realize a small and lightweight design. Finally, the introduction of a thermal conductive layer and a chip package can shorten the heat dissipation path of the chip, increase the heat dissipation channel, and reduce the thermal resistance. Compared with conventional TO or in-line packaged devices, the heat dissipation capacity is greatly improved, and it is easy to realize the expansion of high-density multi-chip area array structure

The packaging module of the present disclosure can be used for lidar/distance detection applications, which can provide a large static FOV with low scanning blind area, high response speed, and low distributed inductance circuit drive. For fiber coupling applications, the packaging module can significantly reduce the BPP value of the multi-single tube/point packaging, and reduce the difficulty of light spot matching for fiber coupling. Finally, the packaging module of the present disclosure can also be used for multi-line/area array light sources, and it is easy to expand the power of the light source, thereby achieving higher power application output.

With the development of science and technology, detection and measurement technologies are being applied in various fields. Lidar is a perception system of the outside world, which can learn the three-dimensional information of the outside world, and is no longer limited to the plane perception of the outside world, such as a camera. The principle is to actively emit laser pulse signals out, detect the reflected pulse signals, determined the distance of the measured object based on the time different between the emission and the reception, and combine the emission angle information of the light pulse to reconstruct the three-dimensional depth information.

An embodiment of the present disclosure provides a distance detection device, which can be used to measure the distance of an object to be detected to the detection device, and the orientation of the object to be detected relative to the detection device. In one embodiment, the detection device may include a radar, such as a lidar. The detection device can detect the distance between the detection device and the object to be detected by measuring the time of light propagation between the detection device and the object to be detected, that is, the time-of-flight (TOF).

When the packaging module of the present disclosure is used as a light source, the driver module may provide a pulse current signal of a certain waveform, and the laser diode chip may receive the pulse current signal. When the signal intensity exceeds a threshold of the laser diode chip, the laser diode chip may emit a laser signal of the corresponding wavelength. The laser signal may be collimated and/or shaped into a light spot with a certain shape and divergence angle after the sealing body and the shaping element, and continue to be emitted to subsequent application, such as a distance detection application. In the following description, a case where the packaging module of the present disclosure is used as a light source and applied to a distance detection device will be described.

In some embodiments, the distance detection device of the present disclosure may include a distance detection module. The distance detection module the laser diode packaging module in the foregoing embodiments, which can be used to emit a laser pulse sequence; a detector configured to receive at least part of the laser pulse sequence, and obtain the distance between the distance detection device and the object to be measured based on a received light beam, where the reflection may include diffuse reflection.

The distance detection device of the present disclosure will be described in detail below with reference to the accompanying drawings. In the case where there is no conflict between the exemplary embodiments, the features of the following embodiments and examples may be combined with each other.

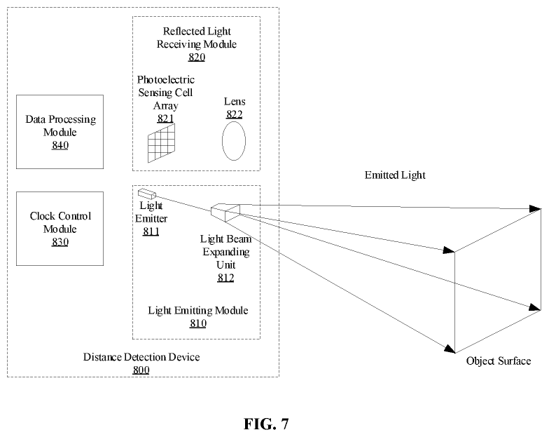

As shown in FIG. 7, an embodiment of the present disclosure provides a distance detection device 800 including a light emitting module 810 and a reflected light receiving module 820. The light emitting module 810 may include at least one laser diode package module described in the foregoing embodiments for emitting optical signals (e.g., the laser pulse sequence), and the optical signals emitted by the optical emitting module 801 may cover the field of view (FOV) of the distance detection device 800. The reflected light receiving module 820 can be used for receiving the reflected light after the light emitted by the light emitting module 810 encounters an object to be measured, and calculating the distance between the distance detection device 800 and the object to be measured. The light emitting module 810 and its working principle will be described below with reference to FIG. 7.

As shown in FIG. 7, the light emitting module 810 includes a light emitter 811 and a light beam expanding unit 812. The light emitter 811 can be used to emit light, and the light beam expanding unit 812 can be used to perform at least one of the processes of collimation, beam expansion, homogenization, and FOV expansion on the light emitted by the light emitter 811 (e.g., the laser pulse sequence emitted by the laser diode packaging module). The light emitted by the light emitter 811 may pass through at least one of the processes of collimation, beam expansion, homogenization, and FOV expansion of the light beam expanding unit 812, such that the emitted light becomes divergent and evenly distributed, which can cover a certain two-dimensional angle in the scene. As shown in FIG. 7, the emitted light can cover at least a part of the surface of the object to be measured.

In one example, the light emitter 811 may be a laser diode, such as the laser diode packaging module of the present disclosure. For the wavelength of the light emitted by the light emitter 811, in one example, light with a wavelength between 895 nanometers and 915 nanometers may be selected, for example, light with a wavelength of 905 nanometers may be selected. In another example, light with a wavelength between 1540 nanometers and 1560 nanometers may be selected. In other examples, other suitable wavelengths of light may also be selected based on the application scenarios and various needs.

Since the light emitter 811 in this embodiment adopts the laser diode packaging module described in the foregoing embodiments of the present disclosure, it can not only include independent single point-line laser light source devices, but also multi-line/area array laser light source devices. For the acquisition of wider and more uniform spatial information, the multi-line/area array transmitting and receiving solution is a better solution. This solution can transmit and receive optical signals of multiple angles/points at the same time, and each angle/point may correspond to different spatial information. Corresponding to the single point/line solution, the multi-line/area array solution will have higher spatial resolution (multiple points can be detected with the same width) and wider FOV range. In the dynamic operational amplifier system, the multi-line/area array light source can realize simultaneous multi-bema multi-thread path scanning, which has a higher cover rage of the target, that is, the detection result is more accurate.

In one example, the light beam expanding unit 812 may be realized by a single-stage or multi-stage beam expansion system. The light beam expansion process can be reflective or transmission, or a combination of the two. In one example, a holographic filter may be used to obtain a large-angle beam composed of multiple sub-beams.

In another example, a laser diode array may also be used to form multiple beams of light with laser diodes to obtain lasers similar to the beam expansion (such as VESEL array lasers).

In another example, a two-dimensional angle adjustable micro-electromechanical system (MEMS) lens may also be used to reflect the emitted light. By driving the MEMS micro-mirrors to constantly change the angle between the mirror surface and the light beam, the angle of the reflected light may be constantly changing, thereby diverging into a two-dimensional angle to cover the entire surface of the object to be measured.

The distance detection device may be used to sense external environmental information, such as distance information, angle information, reflection intensity information, speed information, etc. of a target in the environment. More specifically, the distance detection device in the embodiment of the present disclosure can be applied to a mobile platform, and the distance detection device can be mounted on the platform body of the mobile platform. A mobile platform with a distance detection device can measure the external environment, such as measuring the distance between the mobile platform and an obstacle for obstacle avoidance and other purposes, and for two-dimensional or three-dimensional mapping of the external environment. In some embodiments, the mobile platform may include at least one of an unmanned aerial vehicle (UAV), a car, and a remote control car. When the distance detection device is applied to a UAV, the platform body may be the body of the UAV. When the distance detection device is applied to a car, the platform body may be the body of the car. When the distance detection device is applied to a remote control car, the platform body may be the body of the remote control car.

Since the light emitted by the light emitting module 810 can cover at least a part of the surface or even the entire surface of the object to be measure, correspondingly, the light is reflected after reaching the surface of the object, and the light reaching the reflected light receiving module 820 may not be a single point, but distributed in an array.

The reflected light receiving module 820 may include a photoelectric sensing cell array 821 and a lens 822. After the light reflected from the surface of the object to be measured reaches the lens 822, based on the principle of lens imaging, it can reach the corresponding photoelectric sensing unit in the photoelectric sensing cell array 821, and then be received by the photoelectric sensing unit, causing the photoelectric response of the photoelectric sensing process.

Since in the process of the light being emitted until the photoelectric sensing unit receiving the reflected light, the light emitter 811 and the photoelectric sensing cell array 821 may be controlled by a clock control module to synchronize them (for example, a clock control module 830 shown in FIG. 7 is included in the distance detection device 800, or the clock control module may be outside the distance detection device 800). Therefore, based on the time of flight (TOF) principle, the distance between the point reached by the reflected light and the distance detection device 800 can be determined.

In addition, since the photoelectric sensing unit is not a single point, but a photoelectric sensing cell array 821, therefore, after data process by a data processing module (such as the data processing module 840 shown in FIG. 7 included in the distance detection device 800, or the data processing module may be outside the distance detection device 800), the distance information of all points in the field of view of the entire distance detection device can be obtained. That is, the point cloud data of the distance from the external environment that the detection device faces.

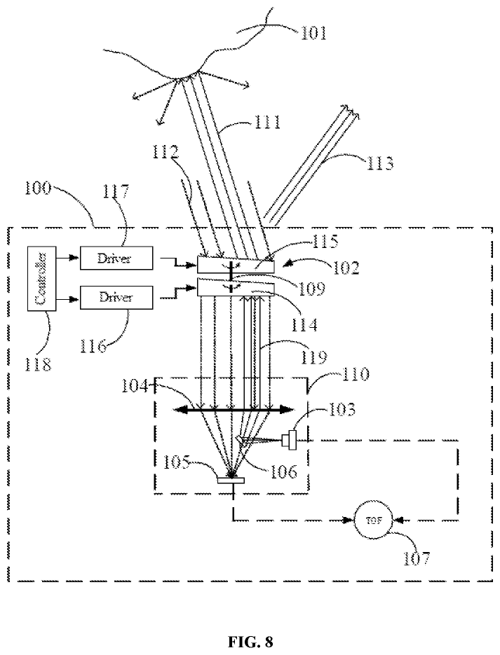

A coaxial optical path may be used in the distance detection device, that is, the light emitted by the detection device and the reflected light share at least a part of the optical path in the detection device. Alternatively, the detection may also use an off-axis optical path, that is, the light emitted by the detection device and the reflected light are transmitted along different optical paths in the detection device. FIG. 8 is a schematic diagram of a distance detection device 100 of the present disclosure.

In another embodiment, as shown in FIG. 8, the distance detection device 100 includes a distance detection module 110, and the distance detection module 110 includes a light source 103, a collimating element 104 (such as a collimating lens), a detector 105, and an optical path changing element 106. The distance detection module 110 may be configured to emit a light beam, receive a returned light, and convert the returned light into an electrical signal. The light source 103 may be used to emit a light beam. In one embodiment, the light source 103 may emit a laser beam. The light source 103 may include the laser diode packaging module described in the foregoing embodiments, and may be configured to emit a laser pulse sequence. The collimating element 104 may be used to collimate the laser pulse sequence emitted by the laser diode packaging module and emit it, and/or converge at least part of the returned light reflected by the objected to be detected to be detector.

In some embodiments, the distance detection module 110 may further include a carrier board (not shown in the accompanying drawings) and two or more laser diode packaging modules disposed on the carrier board. The two or more laser diode packaging modules may be disposed along any straight line or in an array on the carrier board.

In some embodiments, the two or more laser diode packaging modules may be stacked and disposed in a direction parallel to the surface of the carrier board. Alternatively, the two or more laser diode packaging modules may be stacked and disposed in a direction perpendicular to the surface of the carrier board.

Since the distance detection module 110 in this embodiment uses the laser diode packaging module described in the embodiments of the present disclosure as a light source, it may not only include independent single point/line laser light source devices, but also multi-line/area array laser light source devices. For the acquisition of wider and more uniform spatial information, the multi-line/area array transmitting and receiving solution is a better solution. This solution can transmit and receive optical signals of multiple angles/points at the same time, and each angle/point may correspond to different spatial information. Corresponding to the single point/line solution, the multi-line/area array solution will have higher spatial resolution (multiple points can be detected with the same width) and wider FOV range. In the dynamic operational amplifier system, the multi-line/area array light source can realize simultaneous multi-bema multi-thread path scanning, which has a higher cover rage of the target, that is, the detection result is more uniform.

The distance detection device 100 may further include a scanning module 102 for sequentially changing the propagation direction of the laser pulse sequence emitted by the distance detection module to emit, and at least part of the light beam reflected by the object may enter the distance detection module after passing through the scanning module 102. The scanning module 102 may be placed on the exit light path of the distance detection module 110. The scanning module 102 may be configured to change the transmission direction of a collimated light beam 119 emitted by the collimating element 104 and projecting it to the external environment, and projecting the returned light to the collimating element 104. The returned light may be collected by the detector 105 via the collimating element 104.

In one embodiment, the scanning module 102 may include one or more optical elements, such as a lens, a mirror, a prism, a grating, an optical phased array, or any combination of the foregoing optical elements. In one embodiment, the scanning module may include at least one prism whose thickness may vary in a radial direction and a driver such as a motor for driving the prism to rotate. The rotating prism may be used to refract the laser pulse sequence emitted by the distance detection module to different directions. In some embodiments, the plurality of optical elements of the scanning module 102 may rotate around a common axis 109, and each rotating optical element may be used to continuously change the propagation direction of the incident light beam. In one embodiment, the plurality of optical elements of the scanning module 102 may rotate at different rotation speeds. In another embodiment, the plurality of optical elements of the scanning module 102 may rotate at substantially the same rotation speed.

In some embodiments, the plurality of optical elements of the scanning module may also rotate around different axes, or vibrate in the same direction, or vibrate in different directions, which is not limited here.

In one embodiment, the scanning module 102 may include a first optical element 114 and a driver 116 connected to the first optical element 114. The driver 116 may be configured to drive the first optical element 114 to rotate around the rotation axis 109, such that the first optical element 114 may change the direction of the collimated light beam 119. The first optical element 114 may project the collimated light beam 119 to different directions. In one embodiment, the angle between the direction of the collimated light beam 119 changed by the first optical element and the rotation axis 109 may change with the rotation of the first optical element 114. In one embodiment, the first optical element 114 may include a pair of opposite non-parallel surfaces through which the collimated light beam 119 may pass. In one embodiment, the first optical element 114 may include a wedge-angle prism to collimate the collimated light beam 119 for refracting. In one embodiment, the first optical element 114 may be coated with an anti-reflection coating, and the thickness of the anti-reflection coating may be equal to the wavelength of the light beam emitted by the light source 103, which can increase the intensity of the transmitted light beam.

In the embodiment shown in FIG. 8, the scanning module 102 includes a second optical element 115. The second optical element 115 may rotate around the rotation axis 109, and the rotation speed of the second optical element 115 may be different from the rotation speed of the first optical element 114. The second optical element 115 may be configured to change the direction of the light beam projected by the first optical element 114. In one embodiment, the second optical element 115 may be connected to another driver 117, and the driver 117 may be configured to drive the second optical element 115 to rotate. The first optical element 114 and the second optical element 115 may be driven by different drivers, such that the rotation speed of the first optical element 114 and the second optical element 115 may be different. As such, the collimated light beam 119 can be projected to different directions in the external space, and a larger spatial range can be scanned. In one embodiment, a controller 118 may control the driver 116 and the driver 117 to drive the first optical element 114 and the second optical element 115, respectively. The rotation speeds of the first optical element 114 and the second optical element 115 may be determined based on the area and pattern expected to be scanned in actual applications. The drivers 116 and 117 may include motors or other driving devices.

In one embodiment, the second optical element 115 may include a pair of opposite non-parallel surfaces through which the light beam may pass. The second optical element 115 may include a wedge-angle prism. In one embodiment, the second optical element 115 may be coated with an anti-reflection coating to increase the intensity of the transmitted light beam.

The rotation of the scanning module 102 may project light to different directions, such as a direction 111 and a direction 113, thereby scanning the space around the detection device 100. When the light in the direction 111 projected by the scanning module 102 hits an object to be detected 101, a part of the light may be reflected by the object to be detected 101 to the detection device 100 in a direction opposite to the direction 111 of the projected light. The scanning module 102 may receive a returned light 112 reflected by the object to be detected 101 and project the returned light 112 to the collimating element 104.

The collimating element 104 may be configured to converge at least a part of the returned light 112 reflected by the object to be detected 101. In one embodiment, an anti-reflection coating may be coated on the collimating element 104 to increase the intensity of the transmitted light beam. The detector 105 and the light source 103 may be disposed on the same side of the collimating element 104, and the detector 105 may be configured to convert at least a part of the returned light passing through the collimating element 104 into an electrical signal. In some embodiments, the detector 105 may include an avalanche photodiode. The avalanche photodiode is a highly sensitive semiconductor device that can convert an optical signal into an electrical signal using the photocurrent effect.

In some embodiments, the distance detection device 100 may include a measuring circuit, such as a TOF unit 107, which can be used to measure TOF to measure the distance of the object to be detected 101. For example, the TOF unit 107 can calculate the distance by the formula of t=2D/c, where D is the distance between the detection device and the object to be detected, c is the speed of light, and t is the total time it takes for the light to project from the detection device to the object to be detected and returned from the object to be detected to the detection device. The distance detection device 100 can determine the time t based on the time difference between the light emitted by the light source 103 and the returned light received by the detector 105, and then the distance D may be determined. The distance detection device 100 can also detect the position of the object to be detected 101 relative to the distance detection device 100. The distance and orientation detected by the distance detection device 100 can be used for remote sensing, obstacle avoidance, surveying and mapping, modeling, navigation, and the like.

In some embodiments, the light source 103 may include a laser diode, through which nanosecond laser light can be emitted. For example, the laser pulse emitted by the light source 103 may last for 10 ns, and the pulse duration of the returned light detected by the detector 105 may be substantially the same as the emitted laser pulse duration. Further, the laser pulse receiving time may be determined. For example, by detecting the rising edge time and/or falling edge time of the electrical signal pulse to determine the laser pulse receiving time. In some embodiments, multi-stage amplification may be performed on the electrical signal. As such, the distance detection device 100 can calculate the TOF by using the pulse receiving time information and the pulse sending time information, thereby determining the distance between the object to be detected 101 and the distance detection device 100.

Based on the foregoing structure and working principle of the laser diode package module based on the embodiments of the present disclosure and the structure and working principle of the distance detection device based on the embodiment of the present disclosure, those skilled in the art can understand the structure and working principle of the electronic device based on the embodiments of the present disclosure. For brevity, detailed will not be repeated here.

A person having ordinary skill in the art can appreciate that units and algorithms of the disclosed methods and processes may be implemented using electrical hardware, or a combination of electrical hardware and computer software. Whether the implementation is through hardware or software is to be determined based on specific application and design constraints. A person of ordinary skill in the art may use different methods to realize different functions for each specific application. Such implementations fall within the scope of the present disclosure

Those skilled in the art should realize that the present disclosure can be implemented electronic hardware, or a combination of computer software and electronic hardware. Whether these functions are performed by hardware or software may depend on the specific applications and design constraints. Those skilled in the art can use different methods to achieve the described functions for each of the specific applications, but such achievement should not be considered to exceed the scope of the present disclosure.

In the several embodiments provided by the present disclosure, it should be understood that the disclosed apparatus and method may be implemented in other manners. For example, the apparatus embodiments described above are merely illustrative. For example, the unit division is merely logical function division and there may be other division in actual implementation. For example, multiple units or components may be combined or integrated into another system, or some features can be omitted or not be executed.

In the specification provided herein, a plenty of particular details are described. However, it can be appreciated that embodiments of the present disclosure may be practiced without these particular details. In some embodiments, well known methods, structures and technologies are not illustrated in detail so as not to obscure the understanding of the specification.

Similarly, it shall be appreciated that in order to simplify the present disclosure and help the understanding of one or more of all the inventive aspects, in the above description of the exemplary embodiments of the present disclosure, sometimes individual features of the invention are grouped together into a single embodiment, figure or the description thereof. However, the disclosed methods should not be construed as reflecting the following intention, namely, the claimed invention claims more features than those explicitly recited in each claim. More precisely, as reflected in the following claims, an aspect of the invention lies in being less than all the features of individual embodiments disclosed previously. Therefore, the claims complying with a particular implementation are hereby incorporated into the particular implementation, wherein each claim itself acts as an individual embodiment of the present disclosure.

Those skilled in the art can understand that in additional to mutual exclusion between the features, all the features disclosed in the specification (including the accompanying claims, abstract and drawings) and all the procedures or units of any method or device disclosed as such may be combined employing any combination. Unless explicitly stated otherwise, each feature disclosed in the specification (including the accompanying claims, abstract and drawings) may be replaced by an alternative feature providing an identical, equal or similar objective.

Furthermore, it can be appreciated to the skilled in the art that although some embodiments described herein comprise some features and not other features comprised in other embodiment, a combination of features of different embodiments is indicative of being within the scope of the invention and forming a different embodiment. For example, in the following claims, any one of the claimed embodiments may be used in any combination.

Each embodiment of the present disclosure may be implemented by hardware or implemented by a software module operating on one or more processors or implemented by a combination of the hardware and the software module. A person skilled in the art should understand that partial or complete functions of some or all components in the device for data matching according to the embodiment of the present disclosure may be implemented by using a microprocessor or a digital signal processor (DSP) in practice. The present disclosure may be further implemented as a program of a device or apparatus (such as a computer program and a computer program product) to be configured to partially or completely perform the method described here. The program realizing the present disclosure may be stored in a computer readable medium, or may have one or more signal types. The signals may be downloaded from an Internet website or provided by a carrier signal or provided in any other form.

It should be noted that the embodiments above are illustrations rather than limitations on the present disclosure; moreover, a person skilled in the art may design substituting embodiments in case of not deflecting from scope of accompanying claims. In the claims, any reference signs in brackets shall not be construed as a limitation on the claims. The present disclosure may be implemented by hardware including a plurality of different elements as well as a properly programmed computer. In a claim listing a plurality of apparatus units, several of the apparatus units may be specifically implemented by a same hardware item. Use of words “first”, “second”, “third”, and the like, does not represent any sequence preference. The words may be explained as names.

Other embodiments of the present disclosure will be apparent to those skilled in the art from consideration of the specification and practice of the embodiments disclosed herein. It is intended that the specification and examples be considered as example only and not to limit the scope of the present disclosure, with a true scope and spirit of the invention being indicated by the following claims. Variations or equivalents derived from the disclosed embodiments also fall within the scope of the present disclosure.

What is claimed is:

1. A laser diode package, comprising:
a sealing body;
a laser diode chip embedded in the sealing body; and
a shaping element disposed on an outer surface of the sealing body and configured to shape light emitted from the laser diode chip.

2. The package of claim 1, wherein:
the shaping element and the sealing body are integrally formed, or the shaping element is fixed on the sealing body by welding or gluing.

3. The package of claim 1, further comprising:
a thermal conductive layer placed in the sealing body, wherein the laser diode chip is disposed on the thermal conductive layer.

4. The package of claim 1, further comprising:
a substrate for carrying the laser diode chip, the substrate being used for mounting on a circuit board.

5. The package of claim 4, further comprising:
a thermal conductive layer including a first surface and a second surface opposite to the first surface, wherein the laser diode chip is disposed on the first surface of the thermal conductive layer, and the second surface is mounted on a surface of the substrate.

6. The package of claim 4, wherein:
the sealing body is mounted on the substrate; or, the sealing body further seals the substrate.

7. The package of claim 1, wherein:
the packaging module includes two or more laser diode chips.

8. The package of claim 7, further comprising:
a thermal conductive layer, the two or more laser diode chips being disposed on the same thermal conductive layer, or each of the two or more laser diode chips being disposed on a different thermal conductive layer.

9. The package of claim 7, wherein:
the two or more laser diode chips are placed in the same sealing body, or different laser diode chips are placed in different sealing bodies.

10. The package of claim 7, wherein:
the packaging module includes two or more layers of the thermal conductive layers arranged in a stack, one or more laser diode chips being disposed on each of the thermal conductive layers.

11. The package of claim 10, further comprising:
a spacer layer, the spacer layer being disposed between two adjacent thermal conductive layers to separate the adjacent thermal conductive layers.

12. The package of claim 10, further comprising:
a substrate for carrying the laser diode chips and the thermal conductive layers, wherein the two or more thermal conductive layers are stacked in a direction parallel to a surface of the substrate, or the two or more thermal conductive layers are stacked in a direction perpendicular to the surface of the substrate.

13. The package of claim 11, wherein:
the spacer layer includes two or more sub-spacers disposed on the thermal conductive layer at intervals.

14. The package of claim 10, wherein:
the two or more laser diode chips are disposed on each layer of the thermal conductive layer, and a light-emitting surface of each laser diode chip faces the same direction.

15. The package of claim 1, wherein:
the shaping element is configured to collimate and/or shape an emitted light speed of the laser diode chip in a fast axis and/or a slow axis direction.

16. The package of claim 1, wherein:
an optical anti-reflection film corresponding to a wavelength of an emitted light emitted by the laser diode chip is plated on a surface of the shaping element.

17. The package of claim 5, wherein:
the laser diode chip includes a first electrode and a second electrode disposed opposite to each other, a surface where the first electrode is positioned being mounted on the first surface of the thermal conductive layer.

18. The package of claim 1, further comprising:
a driver module configured to control the emission of the laser diode chip, the driver module and the laser diode chip being disposed in the same sealing body, or the driver module and the laser diode chip being disposed in different sealing bodies, or the driver module being disposed outside the sealing body.

19. The package of claim 4, further comprising:
a cover disposed on the surface of the substrate, a receiving space being formed between the substrate, wherein
a light-transmitting area is at least partially provided on the cover, the sealing body and the shaping element are disposed in the receiving space, and the light emitted from the shaping element is emitted through the light-transmitting area.

20. A distance detection device comprising:
a distance detection module including a laser diode package configured to emit a laser pulse sequence, the laser diode package including:
a sealing body;
a laser diode chip placed in the sealing body;
a shaping element disposed on an outer surface of the sealing body and configured to shape light emitted from the laser diode chip; and
a detector configured to receive at least part of the laser pulse sequence reflected by an object, and obtain a distance between the distance detection device and the object based on a received light beam.
